(19) United States
(12) Patent Application Publication
(10) Pub. No.: US 2020/0045411 A1
(43) Pub. Date: Feb. 6, 2020

(54) SOUND DEVICE

(71) Applicant: AAC Technologies Pte. Ltd., Singapore City (SG)

(72) Inventor: Lu Feng, Shenzhen (CN)

(21) Appl. No.: 16/524,173

(22) Filed: Jul. 29, 2019

(30) Foreign Application Priority Data
Aug. 1, 2018 (CN) 201821241475.X

(51) Int. Cl. H04R 1/28; H05K 3/36; H04R 1/02; H04R 9/06

(52) U.S. Cl. CPC H04R 1/2811; H05K 3/361; H04R 2499/11; H04R 9/06; H04R 1/026

(57) ABSTRACT

The present disclosure provides a sound device comprising a housing, a sound emitting unit received in the housing, and a flexible circuit board electrically connected to the sound emitting unit, the housing is provided with a snap structure for fixing the flexible circuit board, the snap structure comprises a bottom wall, several sidewalls extending from the bottom wall, a receiving space surrounded by the bottom wall and the plurality of sidewalls, and a snap portion extending from a surface of the sidewall toward the receiving space in a direction approaching the receiving space, the snap portion, the bottom wall, and the sidewalls form a groove, and the flexible circuit board is received in the receiving space with the periphery thereof stuck in the groove.

### TECHNICAL FIELD

The present disclosure relates to the technical field of electro-acoustic conversion, in particular, to a sound device.

### BACKGROUND

Recently, information technology develops rapidly, and audio equipment have become more popular. User's demand for audio equipment is not limited to playback of videos and audios, but there is also a demand for improving reliability of audio equipment. Especially, as 5G era is coming, mobile multimedia technology is also developed, and many audio equipment have a variety of entertainment functions, such as video playback, digital photography, games, GPS navigation, etc. As the demand for functions increases, the integrity of the elements and devices built within the audio apparatuses is getting higher and the requirement for high quality of products becomes stricter.

In audio equipment, a sound device is a commonly used electronic device, it is mainly used for audio signal playback, and the structural design thereof directly affects the quality of audio playback. A sound device according to the related art includes a housing, a sound unit received in the housing, and a flexible circuit board electrically connected to the sound unit. The flexible circuit board is often adhered to the housing by a double-sided tape, however, when assembling, it is necessary to manually tear off the protective paper on the double-sided tape before adhering the double-sided tape. Since the protective paper needs to be manually torn off, which is labor-intensive and is not easy to realize automatic production, and thus the assembly efficiency is relatively low.

Therefore, it is necessary to provide a new sound device to solve the above technical problems.

### BRIEF DESCRIPTION OF THE DRAWINGS

In order to illustrate the technical solutions in the embodiments of the present disclosure more clearly, the drawings used in the description of the embodiments will be briefly described below. It is obvious that the drawings in the following description are only some embodiments of the present disclosure, and to those skilled in the art, other drawings could be obtained according to these drawings without any creative work, wherein:

FIG. 1 is a perspective exploded view illustrating a sound device provided by the present disclosure;

FIG. 2 is a perspective assembly view illustrating the sound device shown in FIG. 1;

FIG. 3 is a schematic structural view illustrating a snap structure in the sound device shown in FIG. 1;

FIG. 4 is a cross-sectional view of the sound device shown in FIG. 2 taken along the line A-A;

FIG. 5 is an enlarged view of part B of the sound device shown in FIG. 4;

FIG. 6 is a cross-sectional view of the sound device shown in FIG. 2 taken along the line C-C;

FIG. 7 is an enlarged view of part D of the sound device shown in FIG. 6.

### DETAILED DESCRIPTION

The technical solutions in the embodiments of the present disclosure will be clearly and completely described in conjunction with the drawings in the embodiments of the present disclosure. It is obvious that the described embodiments are just a part but not all of the embodiments of the present disclosure. All other embodiments obtained by those skilled in the art based on the embodiments of the present disclosure without creative efforts would fall within the scope of the present disclosure.

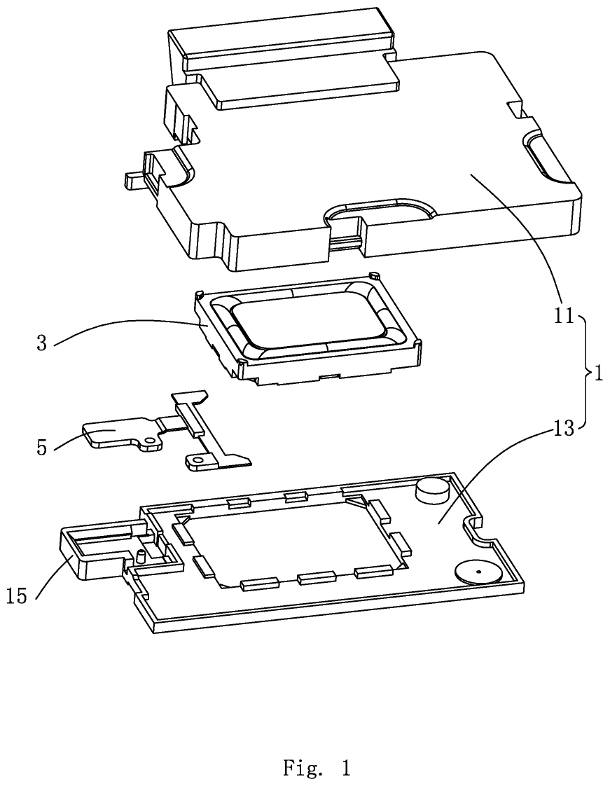

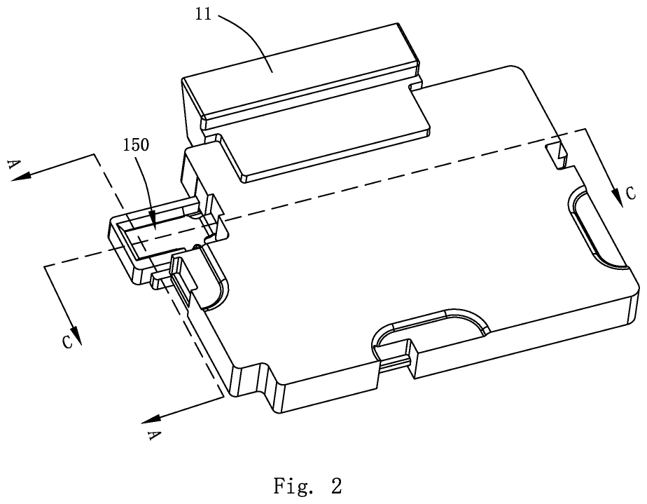

Referring to FIGS. 1 to 2, FIG. 1 is a perspective exploded view illustrating a sound device provided by the present disclosure; and FIG. 2 is a perspective assembly view of the sound device shown in FIG. 1. The present disclosure provides a sound device comprising a housing 1, a sound unit 3 received in the housing 1, and a flexible circuit board 5 electrically connected to the sound unit 3.

The housing 1 includes an upper cover 11, a lower cover 13 fitted with the upper cover 11, and a snap structure 15 for fixing the flexible circuit board 5; and the snap structure 15 is disposed on the lower cover 13.

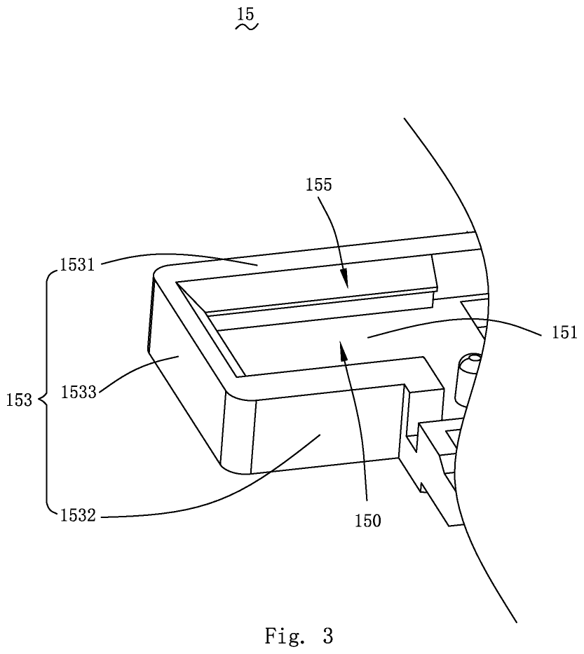

Referring to FIG. 3 as well, FIG. 3 is a schematic structural view of a snap structure in the sound device shown in FIG. 1. The snap structure 15 comprises a bottom wall 151 connected to the lower cover 13, several sidewalls 153 extending from the bottom wall 151, a receiving space formed by the bottom wall 151 and the several sidewalls 153, and a snap portion 155 extending from a surface of the sidewall 153 towards the receiving space 150 in a direction approaching the receiving space 150. The flexible circuit board 5 is received in the receiving space 150. The snap portion 155 abuts against a surface of the flexible circuit board 5.

Referring to FIG. 2 as well, in the embodiment, the bottom wall 151 is configured for supporting. The sidewall 153 comprises a first sidewall 153I, a second sidewall 1532, and a third sidewall 1533 sequentially connected, where the first sidewall 1531 and the second sidewall 1532 are two opposite sidewalls, the third sidewall 1533 is a sidewall disposed between the two opposite sidewalls, and the first sidewall 1531, the second sidewall 1532, and the third sidewall 1533 collectively form the receiving space 150. A part of the flexible circuit board 5 is received in the receiving space 150.

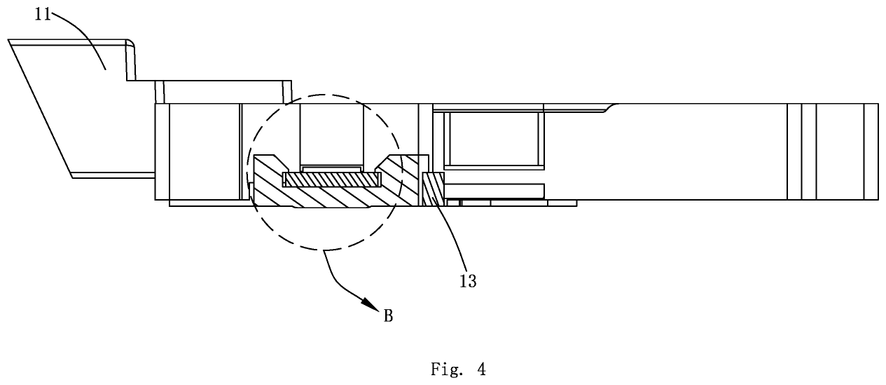

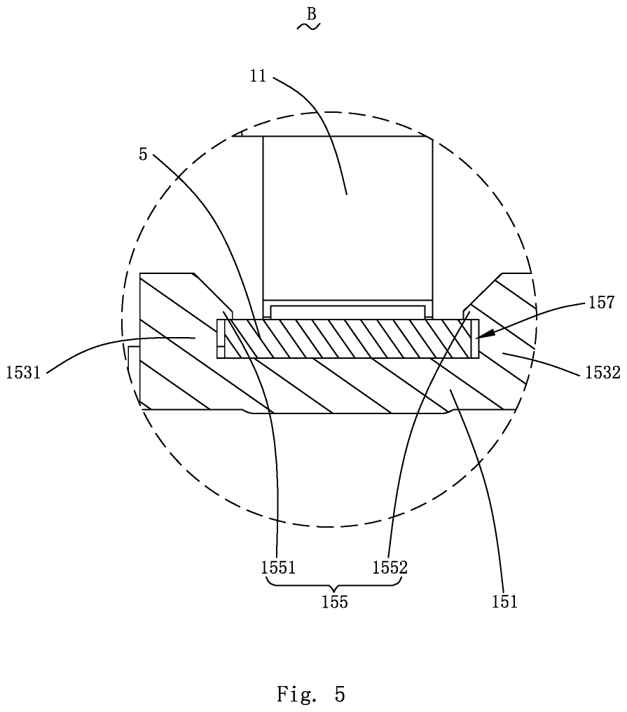

Referring to FIGS. 4 to 5, FIG. 4 is a cross-sectional view of the sound device shown in FIG. 2 taken along the line A-A; and FIG. 5 is an enlarged view of part B of the sound device shown in FIG. 4. The snap portion 155, the bottom wall 151, and the sidewall 153 form a groove 157, and the periphery of the flexible circuit board 5 is stuck in the groove 157 so as to fix the flexible circuit board 5 in the snap structure 15, thus realizing reliable fixing and a simple structure.

Specifically, the snap portion 155 comprises a first snap portion 1551 and a second snap portion 1552 formed by extending from the two opposite sidewalls 153 respectively, the first snap portion 1551 and the second snap portion 1552 abut against the surface of the flexible circuit board 5 for fixing.

In the embodiment, the first snap portion 1551 is formed by extending from a surface of the first sidewall 1531 towards the receiving space 150 in the direction approaching the receiving space 150, the extension herein refers to extending vertically; the second snap portion 1552 is formed by extending from a surface of the second sidewall 1532 towards the receiving space 150 in the direction approaching the receiving space 150, the extension herein refers to extending vertically. Of course, in other embodiments, the first snap portion 1551 could also crookedly extend from the first sidewall 1531, the second snap portion 1552 can also crookedly extend from the second sidewall 1532, or the first snap portion 1551 extends crookedly and the second snap portion 1552 extends vertically, or the first snap portion 1551 extends vertically and the second snap portion 1552 extends crookedly. The extension state of the first snap portion 1551 and the second snap portion 1552 could be designed according to the shape of the flexible circuit board 5 and usage requirements thereof.

Referring to FIG. 5, in the present embodiment, the distance between the two opposite sidewalls 153 is such as greater than the width of the flexible circuit board 5. Specifically, the distance between the first sidewall 1531 and the second sidewall 1532 is slightly larger than the width of the flexible c

Circuit board 5, that is, there is a gap between the first sidewall 1531 and the flexible circuit board 5, and there is also a gap between the second sidewall 1532 and the flexible circuit board 5.

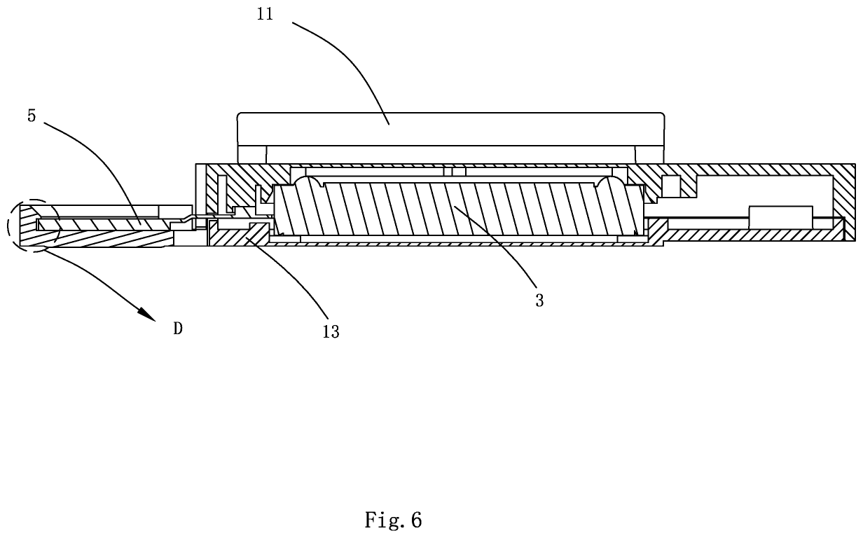

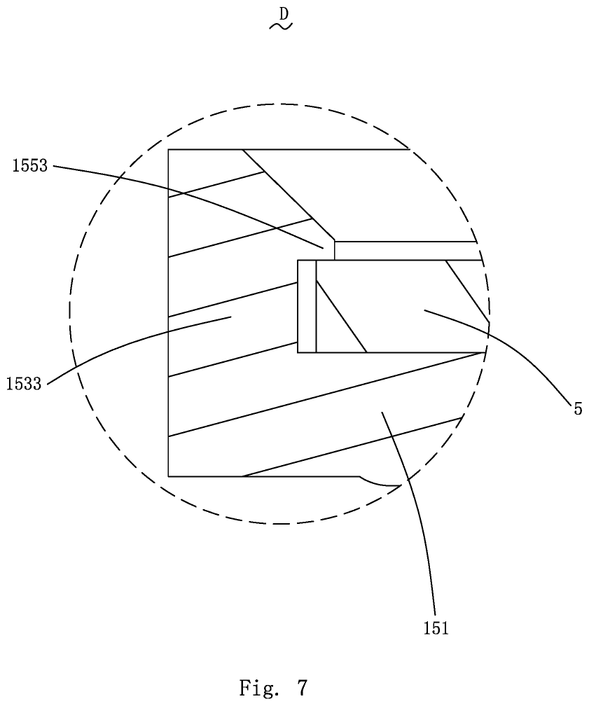

Referring to FIGS. 6 and 7, FIG. 6 is a cross-sectional view of the sound device shown in FIG. 2 taken along the line C-C; and FIG. 7 is an enlarged view of part D of the sound device shown in FIG. 6. In order to fix the flexible circuit board 5 in a better way, the snap portion 155 further comprises a third snap portion 1553 extending from a third sidewall 1533 disposed between the two opposite sidewalls 153. Specifically, the third snap portion 1553 is formed by extending from the surface of the third sidewall 1533 towards the receiving space 150 in the direction approaching the receiving space 150, which extends vertically; of course, in other embodiments, the third snap portion 1553 could also crookedly extend from the third sidewall 1533.

The flexible circuit board 5 is electrically connected to the sound unit 3, and an external circuit transmits an operating current to the sound unit 3 through the flexible circuit board 5 and drives the sound unit 3 to operate, such that the sound device generates sounds.

The sound device provided by the present disclosure is provided with a snap structure 15 on the housing 1 for fixing the flexible circuit board 5, the snap portion 155, the bottom wall 151, and the sidewall 153 form a groove 157, and the periphery of the flexible circuit board 5 is stuck in the groove 157 so that the flexible circuit board is fixed; the flexible circuit board 5 could be directly mounted in the snap structure 15 during assembly, thereby it is easier to realize automatic operation, and thus saving labor and improving assembly efficiency.

The above is only embodiments of the present disclosure, and it should be noted that those skilled in the art can make improvements without departing from the concept of the present disclosure, but these improvements all fall in the protection range of the present disclosure.

What is claimed is:

1. A sound device comprising a housing, a sound unit received in the housing, and a flexible circuit board electrically connected to the sound unit, wherein, the housing is provided with a snap structure for fixing the flexible circuit board;
the snap structure comprises a bottom wall, several sidewalls extending from the bottom wall, a receiving space formed by the bottom wall and the several sidewalls, and a snap portion extending from a surface of the sidewall towards the receiving space in a direction approaching the receiving space; the snap portion, the bottom wall, and the sidewalls form a groove; and the flexible circuit board is received in the receiving space and the periphery thereof stuck in the groove.

2. The sound device according to claim 1, wherein the snap portion comprises a first snap portion and a second snap portion extending from two of the sidewalls opposite to each other, respectively.

3. The sound device according to claim 2, wherein the first snap portion and/or the second snap portion extend vertically from the sidewall.

4. The sound device according to claim 2, wherein the first snap portion and/or the second snap portion extend crookedly from the sidewall.

5. The sound device according to claim 2, wherein a distance between the two opposite sidewalls is greater than a width of the flexible circuit board.

6. The sound device according to claim 2, wherein the snap portion further comprises a third snap portion formed by extending from a sidewall disposed between the two opposite sidewalls.

7. The sound device according to claim 6, wherein the third snap portion extends crookedly or vertically from the sidewall disposed between the two opposite sidewalls.

8. The sound device according to claim 1, wherein the housing comprises an upper cover and a lower cover fitted with the upper cover, and the snap structure is disposed on the lower cover.
